(19) United States
(12) Patent Application Publication
(10) Pub. No.: US 2026/0088798 A1
(43) Pub. Date: Mar. 26, 2026

(54) FILTER DEVICE AND RADIO FREQUENCY FRONT-END CIRCUIT INCLUDING THE SAME

(71) Applicant: Murata Manufacturing Co., Ltd., Nagaokakyo-shi (JP)

(72) Inventor: Akira TANAKA, Nagaokakyo-shi (JP)

(73) Assignee: Murata Manufacturing Co., Ltd., Nagaokakyo-shi (JP)

(21) Appl. No.: 19/315,878

(22) Filed: Sep. 2, 2025

(30) Foreign Application Priority Data
Sep. 26, 2024 (JP) 2024-167312

(51) Int. Cl. H03H 7/46; H03H 1/00; H03H 7/01

(52) U.S. Cl. CPC H03H 7/46; H03H 1/00; H03H 7/0115; H03H 2001/0085

(57) ABSTRACT

A filter device includes a multilayer body, an input terminal, a ground terminal, first and second terminals, and first and second filter circuits. The first filter circuit includes first and second coils connected to in series between the input terminal and the first terminal. The filter circuit includes a third coil connected between the ground terminal and a signal path coupling the input terminal and the second terminal, and a fourth coil between the second terminal and the ground terminal. Each of the first coil and the fourth coil have a winding axis in a direction that extends in a stacking direction. Each of the second coil and the third coil has a winding axis in a direction that intersects the stacking direction. In plan view in the stacking direction, at least part of the first coil and the fourth coil are in between the second and the third coil.

### CROSS-REFERENCE TO RELATED APPLICATION

The present application claims priority to Japanese patent application JP2024-167312, filed Sep. 26, 2024, the entire contents of which being incorporated herein by reference.

### BACKGROUND

### 1. Field

The present disclosure relates to a filter device and a radio frequency front-end circuit including the filter device, and more particularly, relates to a technique to suppress a decrease in characteristics of a diplexer.

### 2. Description of the Related Art

Japanese Unexamined Patent Application Publication No. 2021-19304 discloses a diplexer including, in a dielectric substrate including a plurality of dielectric layers stacked, a filter circuit (high-pass circuit) whose passband is a relatively high frequency band, and a filter circuit (low-pass circuit) whose passband is a relatively low frequency band. In the diplexer disclosed in Japanese Unexamined Patent Application Publication No. 2021-19304, each filter circuit includes a coil having a winding direction in a stacking direction of the dielectric substrate (hereinafter, also referred to as a “planar coil”) and a coil having a winding axis in a direction that intersects the stacking direction (hereinafter, also referred to as a “vertical coil”).

### SUMMARY

A filter device as described above may be used in a small-sized mobile terminal, such as a mobile phone and a smartphone. In such an apparatus, a need for reduction in size and thickness is still high, and an increase in functionality may require the addition of a new component inside a housing. Thus, built-in components are also required to be reduced in size and highly integrated.

In this case, a distance between the respective components is reduced inside the housing, so that it is necessary to prevent interference of electromagnetic fields between electronic components. Therefore, for each electronic component, a metal shield may be disposed at an outer periphery of the component to take a measure to suppress an effect of electromagnetic noise from outside.

In a diplexer, generally, a coil (inductor) and a capacitor that form a resonator of a filter circuit are included. This coil forms an electromagnetic field. However, when another electronic component including a metal shield as described above is brought closer to the diplexer, the electromagnetic field formed by the coil may couple with the metal shield, thus affecting characteristics of the diplexer.

The present disclosure is made in order to solve the problem as described above, and the disclosure is directed to improving robustness to an external metal shield in a filter device (diplexer) having two different passbands.

A filter device according to the present disclosure includes a multilayer body including a plurality of dielectric layers stacked on one another, an input terminal, a ground terminal, a first terminal, a second terminal, a first filter circuit, and a second filter circuit. The first filter circuit is connected between the input terminal and the first terminal. The second filter circuit is connected between the input terminal and the second terminal. The multilayer body includes a first principal surface and a second principal surface opposed to one another. The input terminal, the ground terminal, the first output terminal, and the second output terminal are disposed at the second principal surface. The first filter circuit has a first frequency band as a passband. The second filter circuit has a second frequency band higher than the first frequency band as a passband. The first filter circuit includes a first coil connected to the input terminal, and a second coil connected between the first coil and the first terminal. The second filter circuit includes a third coil connected between the ground terminal and a signal path coupling the input terminal and the second terminal, and a fourth coil connected between the ground terminal and a position in the signal path closer to the second terminal than the third coil. Each of the first coil and the fourth coil is a coil having a winding axis in a first direction that extends in a stacking direction of the multilayer body. Each of the second coil and the third coil is a coil having a winding axis in a second direction that intersects the stacking direction. In plan view in the stacking direction, at least part of the first coil and at least part of the fourth coil are disposed in a first region between the second coil and the third coil.

In the filter device (diplexer) according to the present disclosure, the first coil close to the input terminal in the low-band-side filter circuit (first filter circuit) and the fourth coil close to the second terminal in the high-band-side filter circuit (second filter circuit) are constituted by planar coils. Then, at least part of each of the first coil and the fourth coil is disposed in the region between the second coil of the first filter circuit and the third coil of the second filter circuit, which are constituted by vertical coils.

The first coil and the fourth coil that require a comparatively large inductance value are constituted by planar coils and the other coils are constituted by vertical coils. This can suppress influence of an external metal shield while securing an inductance value with the minimum number of planar coils in the filter device. Furthermore, by the first coil and the fourth coil being disposed between the second coil and the third coil that are vertical coils, a distance between the second coil and the third coil can be secured, which can weaken coupling between the low-band-side filter circuit and the high-band-side filter circuit. This can improve robustness to an external metal shield while suppressing decrease in filter characteristics.

### BRIEF DESCRIPTION OF THE DRAWINGS

FIG. 1 is a block diagram of a communication device including a radio frequency front-end circuit to which a filter device of Embodiment 1 is applied;

FIG. 2 is an equivalent circuit diagram of the filter device according to Embodiment 1;

FIG. 3 is an outline drawing of the filter device according to Embodiment 1;

FIG. 4 is an exploded perspective view of one example of a detailed structure of the filter device in FIG. 3;

FIG. 5 is a plan view for explaining arrangement of coils included in the filter device in FIG. 3;

FIG. 6 is a side transparent view of the filter device in FIG. 3;

FIG. 7 is a diagram for explaining filter characteristics of the filter device of Embodiment 1 and a filter device of a comparative example;

FIG. 8 is a plan view of a filter device of Modification 1;

FIG. 9 is a plan view of a filter device of Modification 2;

FIG. 10 is a side transparent view of a filter device of Modification 3; and

FIG. 11 is a block diagram of a communication device including a radio frequency front-end circuit to which a filter device of Embodiment 2 is applied.

### DETAILED DESCRIPTION

Embodiment 1 of the present disclosure is described below in detail with reference to the drawings. Note that the same reference characters are given to the same or corresponding parts in the drawings and redundant descriptions are omitted.

### Embodiment 1

### Basic Configuration of Communication Device

FIG. 1 is a block diagram of a communication device 10 including a radio frequency front-end circuit 20 to which a filter device 100 according to Embodiment 1 is applied. The radio frequency front-end circuit 20 splits radio frequency signals received by an antenna device ANT into a plurality of frequency bands determined in advance and transmits the split radio frequency signals to a subsequent processing circuit. The radio frequency front-end circuit 20 is used in a communication device, for example, a mobile terminal, such as a mobile phone, a smartphone, or a tablet, or a personal computer having a communication function.

With reference to FIG. 1, the communication device 10 includes the radio frequency front-end circuit 20 including the filter device 100, and an RF signal processing circuit (hereinafter, also referred to as an “RFIC”) 30. The radio frequency front-end circuit 20 illustrated in FIG. 1 is a reception-type front-end circuit. The radio frequency front-end circuit 20 includes the filter device 100 and amplifier circuits LNA1 and LNA2.

The filter device 100 includes an antenna terminal TA that is a common terminal, terminals T1 and T2, and filter circuits FLT1 and FLT2. The filter device 100 is a diplexer including the filter circuit FLT1 and the filter circuit FLT2 whose passbands are frequency ranges different from one another. In the description hereinafter, the filter device 100 may be referred to as “diplexer”. Note that herein “passband” of the filter circuit is a frequency band between two frequencies where insertion loss is higher than a minimum value by 3 dB.

The filter circuit FLT1 is connected between the antenna terminal TA and the terminal T1. The filter circuit FLT1 is a low pass filter whose passband is a frequency range of a low-band (LB) group (first frequency band) and whose non-passband is a frequency range of a high-band (HB) group (second frequency band). The filter circuit FLT2 is connected between the antenna terminal TA and the terminal T2. The filter circuit FLT2 is a high pass filter whose passband is the frequency range of the high-band group and whose non-passband is the frequency range of the low-band group. Note that the filter circuits FLT1 and FLT2 may be band pass filters.

Each of the filter circuits FLT1 and FLT2 allows a radio frequency signal corresponding to the passband of each filter to pass therethrough among radio frequency signals received by the antenna device ANT. Thus, radio frequency signals received by the antenna device ANT are split into signals in a plurality of frequency bands determined in advance.

Each of the amplifier circuits LNA1 and LNA2 is a so-called low-noise amplifier. The amplifier circuits LNA1 and LNA2 amplify, with low noise, radio frequency signals that have passed the filter device 100 and transmit the amplified radio frequency signals to the RFIC 30.

The RFIC 30 is an RF signal processing circuit that processes a radio frequency signal transmitted and received by the antenna device ANT. Specifically, the RFIC 30 performs signal processing by down-conversion or the like of a radio frequency signal input from the antenna device ANT through a reception-side signal path of the radio frequency front-end circuit 20, and outputs a reception signal generated by the signal processing to a baseband signal processing circuit (not illustrated).

In a case in which the radio frequency front-end circuit 20 is a reception-type front-end circuit as in FIG. 1, in the filter device 100, the antenna terminal TA is an input terminal IN, and the terminal T1 and the terminal T2 are respectively a first output terminal OUT1 and a second output terminal OUT2.

On the other hand, the radio frequency front-end circuit can be used as a transmission-type front-end circuit. In this case, each of the terminal T1 and the terminal T2 of the filter device 100 is an input terminal, and the antenna terminal TA is a common output terminal. In this case, as an amplifier included in the amplifier circuit, a power amplifier is used instead of the low-noise amplifier.

### Configuration of Filter Device

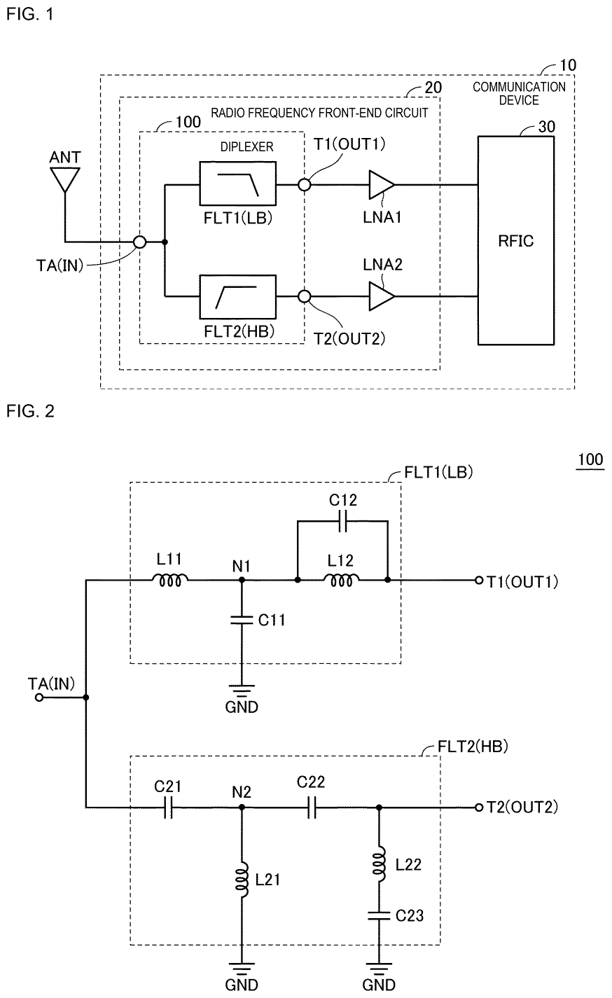

FIG. 2 is a diagram illustrating one example of an equivalent circuit of the filter device (diplexer) 100 in FIG. 1. As described in FIG. 1, the filter circuit FLT1 is connected between the antenna terminal TA and the terminal T1. Further, the filter circuit FLT2 is connected between the antenna terminal TA and the terminal T2. Each of the filter circuits FLT1 and FLT2 includes an LC resonator including a capacitor and an inductor. Note that, in the following description, the inductor is also referred to as a “coil”.

The filter circuit FLT1 includes coils L11 and L12 and capacitors C11 and C12, and is connected between the antenna terminal TA and the terminal T1. A first end of the coil L11 is connected to the antenna terminal TA. A second end of the coil L11 is connected to the terminal T1 with the coil L12 interposed therebetween. That is, the coils L11 and L12 are connected to one another in series between the antenna terminal TA and the terminal T1. This series combination is connected between the ground terminal GND and the signal path at a node between the capacitor C22 and the terminal T2.

The capacitor C11 is connected between a ground terminal GND and a connection node N1 between the coil L11 and the coil L12. The capacitor C12 is connected in parallel with the coil L12. With such a configuration, the filter circuit FLT1 functions as a low pass filter whose passband is a frequency band lower than a given cutoff frequency.

The filter circuit FLT2 includes coils L21 and L22 and capacitors C21 to C23, and is connected between the antenna terminal TA and the terminal T2. A first end of the capacitor C21 is connected to the antenna terminal TA. A second end of the capacitor C21 is connected to the terminal T2 with the capacitor C22 interposed therebetween. That is, the capacitors C21 and C22 are connected to one another in series between the antenna terminal TA and the terminal T2.

The coil L21 is connected between the ground terminal GND and a connection node N2 between the capacitor C21 and the capacitor C22. A first end of the coil L22 is connected to the terminal T2, and a second end of the coil L22 is connected to the ground terminal GND with the capacitor C23 interposed therebetween. That is, in the signal path coupling the antenna terminal TA and the terminal T2 to one another, the coil L22 is connected between the ground terminal GND and a position closer to the terminal T2 than the coil L21. With such a configuration, the filter circuit FLT2 functions as a high pass filter whose passband is a frequency band higher than a given cutoff frequency.

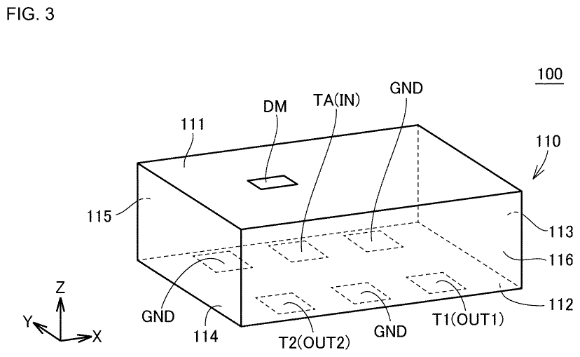

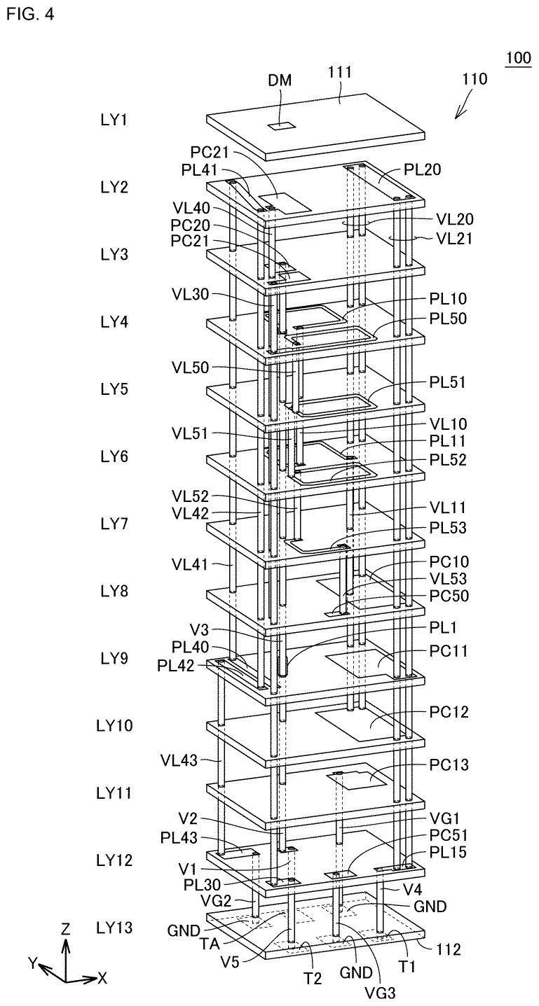

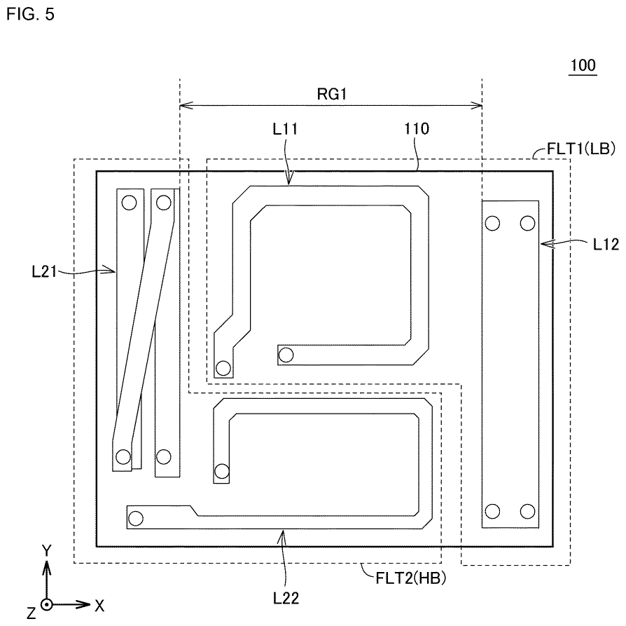

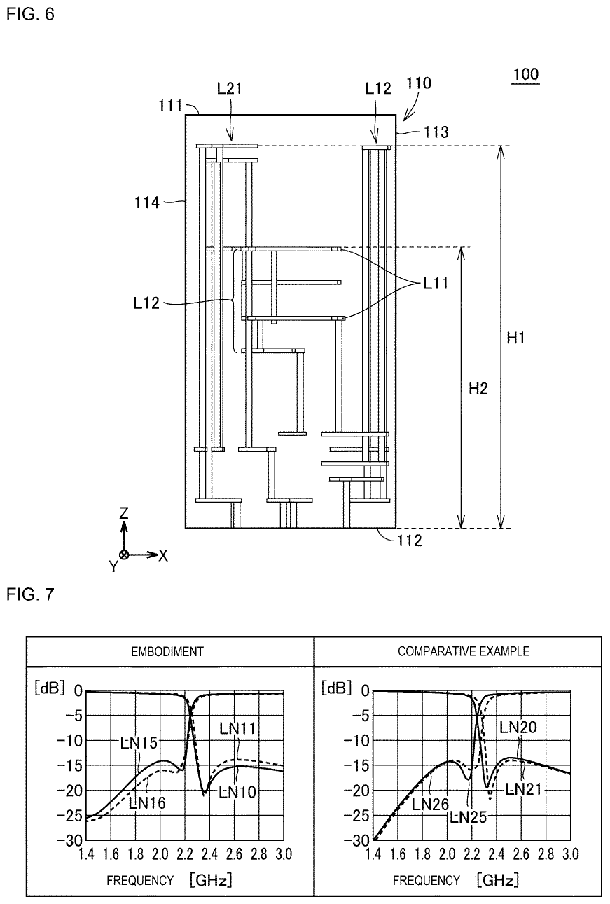

Next, a detailed configuration of the filter device 100 is described with reference to FIGS. 3 to 6. FIG. 3 is an outline drawing of the filter device 100. FIG. 4 is an exploded perspective view of one example of a detailed internal structure of the filter device 100. FIG. 5 is a plan view for explaining arrangement of the coils L11, L12, L21, and L22 included in the filter device 100. FIG. 6 is a side transparent view of the filter device in FIG. 3.

Note that, in FIGS. 5 and 6, dielectric layers of a multilayer body 110 are omitted, and only electrodes, vias, and conductors of terminals disposed in the multilayer body 110 are illustrated. Moreover, in FIG. 5, electrodes other than the coils L11, L12, L21, and L22 are omitted to facilitate description.

The filter device 100 includes the multilayer body 110 in a rectangular parallelepiped or a substantially rectangular parallelepiped. The multilayer body 110 is formed in such a manner that a plurality of dielectric layers LY1 to LY13 are stacked on one another in a given direction. Each dielectric layer of the multilayer body 110 is made of, for example, ceramics, such as low temperature co-fired ceramics (LTCC), or resin. In the multilayer body 110, a plurality of electrodes provided to each dielectric layer and a plurality of vias disposed between the dielectric layers form the inductors and capacitors included in the filter circuits FLT1 and FLT2. Moreover, in the following description, a case in which the multilayer body 110 is a multilayer substrate as described above is described as an example to facilitate description. However, the multilayer body 110 may be a substrate with a single layer.

The “via” as used herein indicates a conductor provided in the dielectric layer to connect the electrodes provided to different dielectric layers. The via is formed with, for example, conductive paste, plating, and/or a metal pin.

Moreover, in the following description, the stacking direction of the dielectric layers LY1 to LY13 in the multilayer body 110 is referred to as a “Z-axis direction”, a direction perpendicular to the Z-axis direction and along a long side of the multilayer body 110 is referred to as an “X-axis direction”, and a direction along a short side of the multilayer body 110 is referred to as a “Y-axis direction”. Moreover, a Z-axis positive direction may be referred below to as an upper side, and a Z-axis negative direction may be referred to as a lower side in each drawing.

With reference to FIGS. 3 to 6, the multilayer body 110 includes an upper surface 111, a lower surface 112, and side surfaces 113 to 116. The upper surface 111 (dielectric layer LY1) of the multilayer body 110 includes a direction mark DM disposed to identify a direction of the filter device 100. As illustrated in FIG. 3, the lower surface 112 (dielectric layer LY13) of the multilayer body 110 includes the external terminals (the antenna terminal TA, the terminals T1 and T2, and the ground terminal GND) to connect the filter device 100 and an external apparatus to one another. That is, the antenna terminal TA, the terminal T1, the terminal T2, and the ground terminal GND constitute a land grid array (LGA).

In FIG. 4, schematically, the filter circuit FLT1 is provided to a right-side (X-axis positive direction) portion of the multilayer body 110, and the filter circuit FLT2 is provided to a left-side (X-axis negative direction) portion.

First, details of the filter circuit FLT1 are described. With reference to FIG. 4, the antenna terminal TA disposed at the lower surface 112 (dielectric layer LY13) of the multilayer body 110 is connected by a via V1 and a via V2 to a plate electrode PL1 disposed at the dielectric layer LY9.

When the multilayer body 110 is seen in plan view in the Z-axis direction, the plate electrode PL1 is a linear band-like electrode. The via V2 is connected to a first end of the plate electrode PL1, and a via V3 is connected to a second end of the plate electrode PL1. The via V3 is connected to a plate electrode PL10 disposed at the dielectric layer LY4 and a capacitor electrode PC20 disposed at the dielectric layer LY3.

The plate electrode PL10 is a band-like electrode in a substantially U-shape or O-shape wound around the Z axis. A first end of the plate electrode PL10 is connected to the via V3. A second end of the plate electrode PL10 is connected by a via VL10 to a plate electrode PL11 disposed at the dielectric layer LY6.

The plate electrode PL11 is a band-like electrode in a substantially U-shape or J-shape wound around the Z axis. A first end of the plate electrode PL11 is connected to the via VL10. A second end of the plate electrode PL11 is connected by a via VL11 to a capacitor electrode PC10 disposed at the dielectric layer LY8. The plate electrodes PL10 and PL11 and the vias VL10 and VL11 constitute the coil L11 included in FIG. 2.

The capacitor electrode PC10 is connected by a via VL20 to a plate electrode PL20 disposed at the dielectric layer LY2 and a capacitor electrode PC12 disposed at the dielectric layer LY10. The capacitor electrodes PC10 and PC12 are plate electrodes having a substantially rectangular shape.

When the multilayer body 110 is seen in plan view in the Z-axis direction, at least part of the capacitor electrode PC10 and at least part of the capacitor electrode PC12 overlap a capacitor electrode PC11 disposed at the dielectric layer LY9. The capacitor electrode PC11 is also a plate electrode having a substantially rectangular shape. That is, the capacitor electrodes PC10 and PC12 and the capacitor electrode PC11 constitute the capacitor C12 in FIG. 2.

The capacitor electrode PC11 is connected by a via VL21 to a plate electrode PL15 disposed at the dielectric layer LY12. The plate electrode PL15 is connected by a via V4 to the terminal T1 disposed at the dielectric layer LY13.

Moreover, the via VL21 is also connected to the plate electrode PL20 disposed at the dielectric layer LY2. The plate electrode PL20 is an electrode having a substantially rectangular shape and extending in the Y-axis direction. The via VL21 is connected to an end portion of the plate electrode PL20 in the Y-axis negative direction. The via VL20 is connected to an end portion of the plate electrode PL20 in the Y-axis positive direction. That is, the plate electrode PL20 and the vias VL20 and VL21 constitute the coil L12 in FIG. 2.

When the multilayer body 110 is seen in plan view in the Z-axis direction, at least part of the capacitor electrode PC12 overlaps a capacitor electrode PC13 disposed at the dielectric layer LY11. The capacitor electrode PC13 is a plate electrode having a substantially rectangular shape, and is connected by a via VG1 to the ground terminal GND disposed at the dielectric layer LY13. That is, the capacitor electrode PC12 and the capacitor electrode PC13 constitute the capacitor C11 in FIG. 2.

Next, details of the filter circuit FLT2 are described. The capacitor electrode PC20 connected to the via V3 at the dielectric layer LY3 at least partially overlaps a capacitor electrode PC21 disposed at the dielectric layer LY2 when the multilayer body 110 is seen in plan view in the Z-axis direction. The capacitor electrode PC21 is a plate electrode having a substantially rectangular shape and extending in the Y-axis direction. When the multilayer body 110 is seen in plan view in the Z-axis direction, at least part of the capacitor electrode PC21 also overlaps a capacitor electrode PC22 disposed at the dielectric layer LY3.

The capacitor electrode PC22 is connected by a via VL30 to a plate electrode PL30 disposed at the dielectric layer LY12. The plate electrode PL30 is connected by a via V5 to the terminal T2 disposed at the dielectric layer LY13.

That is, the capacitor electrode PC20 and the capacitor electrode PC21 constitute the capacitor C21 in FIG. 2. Moreover, the capacitor electrode PC21 and the capacitor electrode PC22 constitute the capacitor C22 in FIG. 2.

In FIG. 4, although it is slightly difficult to confirm visually, the capacitor electrode PC21 is connected by a via VL40 to a plate electrode PL40 disposed at the dielectric layer LY9. The plate electrode PL40 is a band-like electrode extending in the Y-axis direction, and the via VL40 is connected to a first end of the plate electrode PL40. A via VL41 is connected to a second end of the plate electrode PL40. The via VL41 is connected to a plate electrode PL41 disposed at the dielectric layer LY2.

The plate electrode PL41 is a band-like electrode, and the via VL41 is connected to a first end of the plate electrode PL41, and a via VL42 is connected to a second end of the plate electrode PL41. The via VL42 is connected to a plate electrode PL42 disposed at the dielectric layer LY9.

The plate electrode PL42 is a band-like electrode extending in the Y-axis direction, and the via VL42 is connected to a first end of the plate electrode PL42 and a via VL43 is connected to a second end of the plate electrode PL42. The via VL43 is connected to a plate electrode PL43 disposed at the dielectric layer LY12, and connected by a via VG2 to the ground terminal GND disposed at the dielectric layer LY13. The plate electrodes PL40 to PL42 and the vias VL40 to VL42 constitute the coil L21 in FIG. 2.

The via VL30 connected to the capacitor electrode PC22 is also connected to a plate electrode PL50 disposed at the dielectric layer LY4. The plate electrode PL50 is a band-like electrode in a substantially U-shape or O-shape wound around the Z axis. The via VL30 is connected to a first end of the plate electrode PL50, and a via VL50 is connected to a second end of the plate electrode PL50. The via VL50 is connected to a plate electrode PL51 disposed at the dielectric layer LY5.

The plate electrode PL51 is a band-like electrode in a substantially U-shape or O-shape wound around the same winding axis as that of the plate electrode PL50. The via VL50 is connected to a first end of the plate electrode PL51, and a via VL51 is connected to a second end of the plate electrode PL51. The via VL51 is connected to a plate electrode PL52 disposed at the dielectric layer LY6.

The plate electrode PL52 is a band-like electrode in a substantially U-shape or O-shape wound around the same winding axis as that of the plate electrodes PL50 and PL51. The via VL51 is connected to a first end of the plate electrode PL52, and a via VL52 is connected to a second end of the plate electrode PL52. The via VL52 is connected to a plate electrode PL53 disposed at the dielectric layer LY7.

The plate electrode PL53 is a band-like electrode in a substantially C-shape or J-shape wound around the same winding axis as that of the plate electrodes PL50, PL51, and PL52. The via VL52 is connected to a first end of the plate electrode PL53, and a via VL53 is connected to a second end of the plate electrode PL53. The via VL53 is connected to a capacitor electrode PC50 disposed at the dielectric layer LY8. That is, the plate electrodes PL50 to PL53 and the vias VL50 to VL53 constitute the coil L22 in FIG. 2.

When the multilayer body 110 is seen in plan view in the Z-axis direction, at least part of the capacitor electrode PC50 overlaps a capacitor electrode PC51 disposed at the dielectric layer LY12. The capacitor electrode PC51 is connected by a via VG3 to the ground terminal GND disposed at the dielectric layer LY13. That is, the capacitor electrode PC50 and the capacitor electrode PC51 constitute the capacitor C23 in FIG. 2.

As illustrated in FIGS. 4 and 5, the coil L11 of the filter circuit FLT1 and the coil L22 of the filter circuit FLT2 are planar coils with a winding direction in the Z-axis direction. Moreover, the coil L12 of the filter circuit FLT1 and the coil L21 of the filter circuit FLT2 are vertical coils with a winding direction in the X-axis direction.

In the multilayer body 110, the coil L12 is disposed at an end portion in the X-axis positive direction, and the coil L21 is disposed at an end portion in the X-axis negative direction. In the filter device 100, an opening portion of the coil L12 is opposed to an opening portion of the coil L21.

When the multilayer body 110 is seen in plan view in the Z-axis direction, the coil L11 and the coil L22 are disposed in a region RG1 between the coil L12 and the coil L21. The coil L11 is disposed separately from the coil L22 in the Y-axis positive direction and does not overlap the coil L22.

Moreover, when the multilayer body 110 is seen in plan view in the Z-axis direction, the coil L11 is wound in a clockwise direction (CW direction), and the coil L22 is wound in a counter-clockwise direction (CCW direction).

That is, the winding direction of the coil L11 and the winding direction of the coil L22 are opposite to one another.

Then, as illustrated in FIG. 6, the coils L11 and L22 that are planar coils are disposed in such a manner that a height H2 from the lower surface 112 to a top end is less than a height H1 of the coils L12 and L21 that are vertical coils from the lower surface 112 to a top end. In other words, a distance from the upper surface 111 with respect to the coils L11 and L22 is more than a distance from the upper surface 111 with respect to the coils L12 and L21.

A diplexer like the filter device 100 may be used in a small-sized mobile terminal, such as a mobile phone and a smartphone, as described above. In such an apparatus, a need for reduction in size and thickness is still high, and an increase in functionality may require the addition of a new component inside a housing. Thus, built-in components are also required to be reduced in size and highly integrated. Therefore, a distance between the respective components may be reduced inside the housing of the apparatus, and an electromagnetic field generated from a coil in the filter may couple with a metal shield provided to an adjacent electronic component. As a result, an inductance value of the coil may change and a resonant frequency of the resonator may be shifted from a design value, which may increase loss.

In order to reduce such influence of the external metal shield, a metal shield can be provided to an upper surface side of the diplexer. However, in this case, although fluctuation due to the external metal shield can be suppressed, influence of the metal shield included in the diplexer cannot be avoided and, for example, decrease in characteristics, such as decrease in a quality factor, may be caused. In order to solve such decrease in characteristics, increasing a distance between the internal metal shield and the coil and/or increasing an air core diameter of the coil are necessary. However, this rather increases the size of the apparatus body and becomes a factor of hindering size reduction.

A diplexer including a multilayer structure like the filter device 100 is likely to have a state in which an external metal shield is close to the upper surface 111 side opposite to a mounting surface. In this case, the metal shield has a greater influence on a planar coil that generates an electromagnetic field in a normal direction of the upper surface 111.

On the other hand, in a case in which an inductance value and a quality factor of a coil are desired to be increased, it is necessary to increase the air core diameter and/or the number of windings. Such a coil is more easily achievable with a planar coil than a vertical coil.

Therefore, in the filter device 100 according to Embodiment 1, among coils included in the filter, only coils required to have a relatively large quality factor are constituted by planar coils, and the other coils are constituted by vertical coils. Therefore, influence of a metal shield is reduced while characteristics of the coils are maintained.

More specifically, in the case of the filter device 100, as for the low-band-side filter circuit FLT1, in order for a high-band-side signal not to enter, the coil L11 closest to the antenna terminal TA needs to have a higher impedance, that is, a larger inductance value than the coil L12. Furthermore, as for the high-band-side filter circuit FLT2, in order to achieve impedance matching with an external apparatus connected to the terminal T2, the coil L22 closest to the terminal T2 needs to have a larger inductance value to have a higher impedance than the coil L21. Therefore, in the filter device 100, only the coils L11 and L22 are constituted by planar coils, and the other coils L12 and L21 are constituted by vertical coils.

Moreover, as described in FIG. 6, the coils L11 and L22 that are planar coils are disposed lower than the top end of the coils L12 and L21 that are vertical coils, and disposed as far as possible from the upper surface 111. Therefore, even when an external metal shield is brought closer to the upper surface 111, the external metal shield is less likely to exert influence. That is, robustness to the external metal shield can be improved.

Note that, when influence of the external metal shield is considered, the planar coil may be positioned as closely as possible to the lower surface 112. However, on the lower surface 112 side of the multilayer body 110, the capacitor electrodes included in the capacitor and the external connection terminals (the antenna terminal TA, the terminal T1, the terminal T2, and the ground terminal GND) are disposed, and the RFIC 30 may also be mounted on the lower surface 112. Therefore, when the planar coil is excessively close to the lower surface 112, a quality factor may rather be reduced. Thus, a disposed position of the planar coil in the Z-axis direction is designed in consideration of influence of the external metal shield and influence of the electrodes and the like on the lower surface 112 side.

Moreover, by the coils L11 and L22 that are planar coils being disposed lower than the top end of the coils L12 and L21 that are vertical coils, near the upper surface 111 of the multilayer body 110, a magnetic field in the X-axis direction caused by the coils L12 and L21 that are vertical coils becomes dominant over a magnetic field in the Z-axis direction. Therefore, even when the external metal shield is brought closer to the upper surface 111 side, coupling with the metal shield is less likely to occur.

Note that the coils L12 and L21 that are vertical coils are disposed in such a manner that the opening portions of the coils are opposed to one another. In this case, generally, it is concerned that magnetic fields generated from the respective coils couple with one another and isolation between a high-band signal and a low-band signal is degraded. However, in the filter device 100 of Embodiment 1, a greater part of the coils L11 and L22 that are planar coils is disposed in the region RG1 between the coil L12 and the coil L21, and therefore, coupling between the coil L12 and the coil L21 is suppressed.

Moreover, although the planar coils L11 and L22 are disposed adjacent to one another, winding directions thereof are opposite to one another, and therefore, coupling between the two coils is suppressed. That is, the arrangement allows isolation between the filter circuit FLT1 and the filter circuit FLT2 to be easily achievable.

### Filter Characteristics

Next, filter characteristics of the filter device 100 of Embodiment 1 are described with reference to FIG. 7.

FIG. 7 is a diagram illustrating a change in insertion loss in the filter device of Embodiment 1 and a filter device of a comparative example when an external metal shield is brought close to a position higher than the upper surface of the multilayer body by 1 mm. Note that, in FIG. 7, the filter device having the configuration disclosed in Japanese Unexamined Patent Application Publication No. 2021-19304 is used as the comparative example.

In FIG. 7, solid lines (LN10, LN15, LN20, and LN25) indicate characteristics in a state without a metal shield, and broken lines (LN11, LN16, LN21, and LN26) indicate characteristics in a state in which a metal shield is brought closer. Moreover, the lines LN10, LN11, LN21, and LN22 indicate characteristics of a low-band-side filter circuit, and the lines LN15, LN16, LN25, and LN26 indicate characteristics of a high-band-side filter circuit.

It can be seen that, in the comparative example in the right figure, in the case in which the metal shield is brought closer (broken lines LN21 and LN25), on both of the high-band side and the low-band side, a frequency at an attenuation pole is shifted higher as compared with the case without a metal shield. Therefore, particularly on the high-band side, insertion loss at a lower limit of a passband increases.

On the other hand, in Embodiment 1 as shown in the left figure, a frequency at an attenuation pole hardly changes in both of the low band and the high band even when the metal shield is brought closer, and change in insertion loss is also small.

As described above, in the filter device of Embodiment 1, by reducing the number of planar coils as much as possible, as well as devising arrangement and a winding direction of each coil, reduction in fluctuation of characteristics due to an external metal shield (improvement in robustness) and securing of isolation between filter circuits are achievable while securing a desired inductance value and quality factor.

The “coil L11”, “coil L12”, “coil L21”, and “coil L22” in Embodiment 1 respectively correspond to a “first coil” to a “fourth coil” of the present disclosure. The “capacitor C11”, “capacitor C12”, “capacitor C21”, “capacitor C22”, and “capacitor C23” in Embodiment 1 respectively correspond to a “first capacitor” to a “fifth capacitor” of the present disclosure. The “filter circuit FLT1” and “filter circuit FLT2” in Embodiment 1 respectively correspond to a “first filter circuit” and a “second filter circuit” of the present disclosure. The “upper surface 111” and “lower surface 112” in Embodiment 1 respectively correspond to a “first principal surface” and a “second principal surface” of the present disclosure. The “Z-axis direction” and “X-axis direction” in Embodiment 1 respectively correspond to a “first direction” and a “second direction” of the present disclosure.

### MODIFICATIONS

Modifications of coil arrangement of a filter device are described below.

### Modification 1

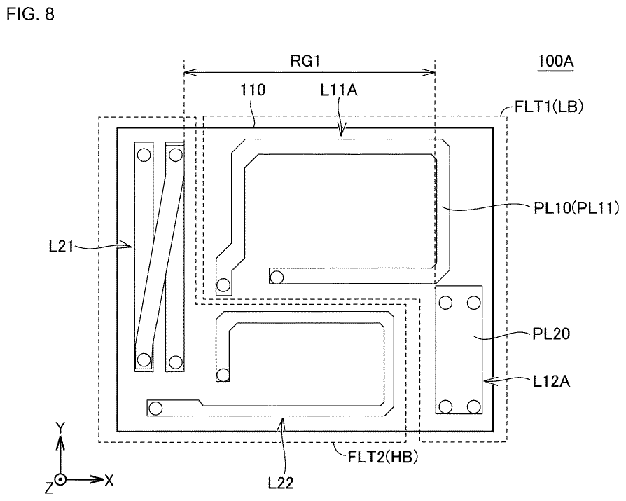

In Modification 1, a different arrangement example of low-band-side coils is described. FIG. 8 is a plan view of a filter device 100A of Modification 1. In the filter device 100A, the coils L11 and L12 in the filter circuit FLT1 of the filter device 100 illustrated in FIG. 5 are respectively replaced by coils L11A and L12A.

With reference to FIG. 8, the coil L12A in the filter circuit FLT1 is shortened in a length of the plate electrode PL20 in the Y-axis direction as compared with the coil L12 in the filter device 100, and the coil L12A is disposed on the side surface 116 side of the multilayer body 110 in the Y-axis negative direction.

Along with this, in the coil L11A, the shapes of the plate electrodes PL10 and PL11 are extended in the X-axis positive direction in such a manner that the air core diameter increases in the X-axis direction as compared with the coil L11 of the filter device 100. Therefore, part of the coil L11A is disposed outside the region RG1.

By the coils having such shapes, a quality factor of the coil L12A slightly decreases as compared with the coil L12 of Embodiment 1, whereas the coil L11A has a larger air core diameter than the coil L11. Therefore, an inductance value can further be increased and a quality factor can be improved.

Moreover, a degree of overlap of the opening portion of the coil L21 and an opening portion of the coil L12A decreases when seen in the X-axis direction, and thus isolation between the filter circuit FLT1 and the filter circuit FLT2 is improved.

Note that, in the filter device 100A illustrated in FIG. 8, a configuration in which the coil L12A is disposed on the side surface 116 side and the coil L11A is extended in the X-axis direction is described. Alternatively, the coil L12A may be disposed on the side surface 115 side, and the coil L22 may be extended in the X-axis direction.

### Modification 2

In Modification 2, a configuration in which the filter device 100A illustrated in FIG. 8 includes a vertical coil in a different shape is described.

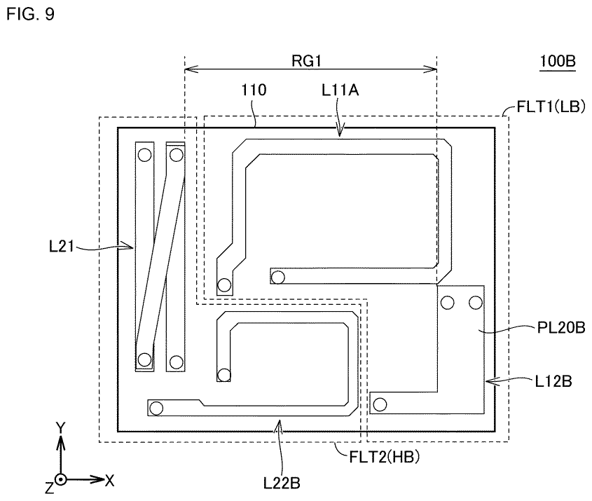

FIG. 9 is a plan view of a filter device 100B of Modification 2. In the filter device 100B, the coil L12A of the filter device 100A is replaced by a coil L12B, and the high-band-side coil L22 is replaced by a coil L22B.

In the coil L12B of the filter device 100B, a plate electrode PL20B disposed at the dielectric layer LY2 has a substantially L-shape. That is, in the coil L12B, part of an opening portion is parallel with a ZX plane.

As a result, a dimension of the coil L12B in the X-axis direction is larger than the coil L12A, and thus the high-band-side coil L22B has a smaller air core diameter than the coil L22.

With such a configuration, the coil L12B has a larger inductance value than the coil L12A. On the other hand, the coil L22B has a smaller inductance value than the coil L22. The shapes and arrangement of the respective coils are suitably selected based on demanded filter characteristics and parameter values of respective elements required to achieve the demanded filter characteristics.

### Modification 3

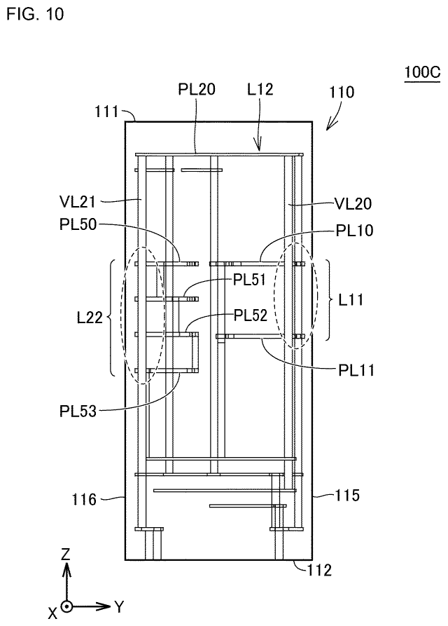

In Modification 3, a modification of arrangement of planar coils is described. FIG. 10 is a side transparent view of a filter device 100C of Modification 3 when seen in the X-axis direction. In the filter device 100C, although the shape of each coil is basically the same as that of the filter device 100 of Embodiment 1, positions of the coils L11 and L22 that are planar coils are different in the Y-axis direction.

More specifically, in the filter device 100C, the coil L11 is disposed at a position slightly offset in the Y-axis positive direction, and the coil L22 is disposed at a position slightly offset in the Y-axis negative direction.

Therefore, as indicated by a broken-line portion in FIG. 10, an end portion of the coil L11 on the side surface 115 side and an end portion of the coil L22 on the side surface 116 side are disposed outside the opening portion of the coil L12 that is a vertical coil. Note that, instead of offsetting the positions of the coils L11 and L22, the air core diameter of the coils L11 and L22 may be extended in the Y-axis direction.

In this way, by the planar coil being disposed in such a manner that the end portion of the planar coil on the side surface side is positioned outside the opening portion of the vertical coil, a portion that does not interfere with the electrode of the vertical coil can be increased. Therefore, the planar coil can have an improved quality factor.

Moreover, in the filter device 100C, in a stacking direction (Z-axis direction), the plate electrode PL51 included in the high-band-side coil L22 is disposed at a dielectric layer between the plate electrodes PL10 and PL11 included in the low-band-side coil L11. Such arrangement can reduce stray capacitance between layers of the low-band-side coil, while efficiently achieving a high inductance value with respect to the high-band-side coil in a space of the dielectric. With such a configuration, a filter device in small size and having high filter characteristics is achievable.

### Embodiment 2

In Embodiment 2, a case in which a radio frequency front-end circuit includes a triplexer that splits signals into three different frequency bands is described.

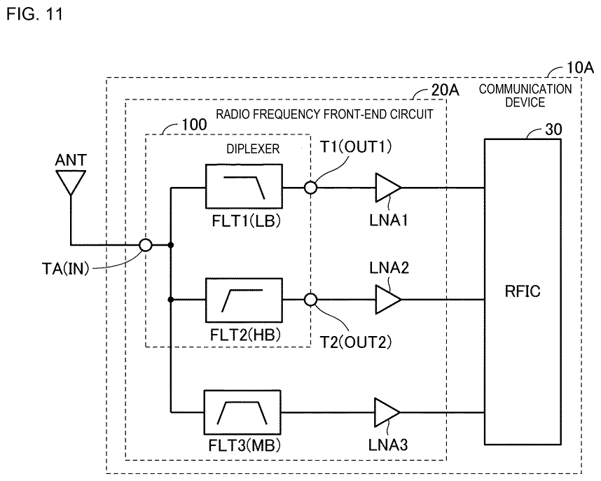

FIG. 11 is a block diagram of a communication device 10A including a radio frequency front-end circuit 20A of Embodiment 2. In the radio frequency front-end circuit 20A, a filter circuit FLT3 and an amplifier circuit LNA3 are added to the radio frequency front-end circuit 20 illustrated in FIG. 1. With respect to FIG. 11, description of elements that overlap those in FIG. 1 is not repeated.

The filter circuit FLT3 is a band pass filter whose passband is a middle-band (MB) frequency band, which is higher than the passband of the low-band-side filter circuit FLT1 and lower than the passband of the high-band-side filter circuit FLT2. A first end of the filter circuit FLT3 is connected to the antenna terminal TA and a second end of the filter circuit FLT3 is connected to the RFIC 30 with the amplifier circuit LNA3 interposed therebetween.

In the filter device 100 that functions as a diplexer, a diplexer having coil arrangement as described in Embodiment 1 is adopted. Therefore, also in the radio frequency front-end circuit 20A of Embodiment 2, similarly to Embodiment 1, improvement in robustness to an external metal shield as well as securing of isolation between filter circuits are achievable while securing a desired inductance value and quality factor.

The “filter circuit FLT3” in Embodiment 2 corresponds to a “third filter circuit”of the present disclosure.

### ASPECTS

It will be understood by a person skilled in the art that the plurality of exemplary embodiments described above are specific examples of the following aspects.

### First Clause

A filter device according to an aspect includes a multilayer body including a plurality of dielectric layers stacked on one another, an input terminal, a ground terminal, a first terminal, a second terminal, a first filter circuit, and a second filter circuit. The first filter circuit is connected between the input terminal and the first terminal. The second filter circuit is connected between the input terminal and the second terminal. The multilayer body includes a first principal surface and a second principal surface opposed to one another. The input terminal, the ground terminal, the first terminal, and the second terminal are disposed at the second principal surface. The first filter circuit has a first frequency band as a passband. The second filter circuit has a second frequency band higher than the first frequency band as a passband. The first filter circuit includes a first coil and a second coil connected to one another in series between the input terminal and the first terminal. The first coil is connected to the input terminal, and the second coil is connected to the first terminal. The second filter circuit includes a third coil connected between the ground terminal and a signal path coupling the input terminal and the second terminal, and a fourth coil connected between the ground terminal and a position in the signal path closer to the second terminal than the third coil. Each of the first coil and the fourth coil is a coil having a winding axis in a first direction that extends in a stacking direction of the multilayer body. Each of the second coil and the third coil is a coil having a winding axis in a second direction that intersects the stacking direction. In plan view in the stacking direction, at least part of the first coil and at least part of the fourth coil are disposed in a first region between the second coil and the third coil.

### Second Clause

In the filter device according to the first clause, in plan view in the first direction, a winding direction of the first coil and a winding direction of the fourth coil are opposite to one another.

### Third Clause

In the filter device according to the first or second clause, in plan view in the first direction, the first coil does not overlap the fourth coil.

### Fourth Clause

In the filter device according to any one of the first to third clauses, a dimension from the first principal surface to the first coil and the fourth coil in the first direction is larger than a dimension from the first principal surface to the second coil and the third coil in the first direction.

### Fifth Clause

In the filter device according to any one of the first to fourth clauses, in plan view in the second direction, at least part of the second coil overlaps the third coil.

### Sixth Clause

In the filter device according to any one of the first to fifth clauses, an inductance value of the first coil is larger than an inductance value of the second coil. An inductance value of the fourth coil is larger than an inductance value of the third coil.

### Seventh Clause

In the filter device according to any one of the first to sixth clauses, at least one of part of the first coil and part of the fourth coil is disposed outside the first region.

### Eighth Clause

In the filter device according to any one of the first to seventh clauses, each of the first coil and the fourth coil includes a plurality of plate electrodes disposed at dielectric layers different from one another, and a plurality of vias extending in the stacking direction. The first coil includes a first plate electrode and a second plate electrode. One or some of the plate electrodes included in the fourth coil are disposed at a dielectric layer between the first plate electrode and the second plate electrode.

### Ninth Clause

In the filter device according to any one of the first to seventh clauses, each of the first coil and the fourth coil includes a plurality of plate electrodes disposed at dielectric layers different from one another, and a plurality of vias extending in the stacking direction. In at least one of the first coil and the fourth coil, an end portion of at least one or some of the plurality of plate electrodes included in the at least one of the first coil and the fourth coil are positioned outside an opening portion of the second coil in plan view in the second direction.

### Tenth Clause

In the filter device according to any one of the first to ninth clauses, the first filter circuit further includes a first capacitor and a second capacitor. The first capacitor is connected between the ground terminal and a connection node between the first coil and the second coil. A second capacitor is connected in parallel with the second coil.

### Eleventh Clause

In the filter device according to any one of the first to tenth clauses, the second filter circuit further includes a third capacitor connected to the input terminal, a fourth capacitor, and a fifth capacitor. The fourth capacitor is connected between the third capacitor and the second terminal. The fifth capacitor is connected between the fourth coil and the ground terminal. The third coil is connected between the ground terminal and a connection node between the third capacitor and the fourth capacitor.

### Twelfth Clause

A radio frequency front-end circuit according to an aspect includes the filter device according to any one of the first to eleventh clauses.

### Thirteenth Clause

The radio frequency front-end circuit according to the twelfth clause further includes a third filter circuit having a third frequency band different from the first frequency band and the second frequency band as a passband.

Embodiment 1 disclosed herein is illustrative and non-restrictive in every respect. The scope of the present invention is defined by the claims, rather than the above description of Embodiment 1, and is intended to include any modifications within the meaning and scope equivalent to the claims.

What is claimed is:

1. A filter device comprising:
a multilayer body including a plurality of dielectric layers stacked on one another, and a first principal surface and a second principal surface opposed to one another;
an input terminal, a ground terminal, a first terminal, and a second terminal disposed at the second principal surface;
a first filter circuit connected between the input terminal and the first terminal and having a first frequency band as a passband; and
a second filter circuit connected between the input terminal and the second terminal and having a second frequency band higher than the first frequency band as a passband, wherein
the first filter circuit includes a first coil and a second coil connected to one another in series between the input terminal and the first terminal, in which
the first coil is connected to the input terminal, and
the second coil is connected to the first terminal,
the second filter circuit includes
a third coil connected between the ground terminal and a signal path coupling the input terminal and the second terminal, and
a fourth coil connected between the ground terminal and a position in the signal path closer to the second terminal than the third coil,
each of the first coil and the fourth coil is a coil having a winding axis in a first direction that extends in a stacking direction of the multilayer body,
each of the second coil and the third coil is a coil having a winding axis in a second direction that intersects the stacking direction, and
in plan view in the stacking direction, at least part of the first coil and at least part of the fourth coil are disposed in a first region between the second coil and the third coil.

2. The filter device according to claim 1, wherein, in plan view in the first direction, a winding direction of the first coil and a winding direction of the fourth coil are opposite to one another.

3. The filter device according to claim 1, wherein, in plan view in the first direction, the first coil does not overlap the fourth coil.

4. The filter device according to claim 1, wherein a dimension from the first principal surface to the first coil and the fourth coil in the first direction is larger than a dimension from the first principal surface to the second coil and the third coil in the first direction.

5. The filter device according to claim 1, wherein, in plan view in the second direction, at least part of the second coil overlaps the third coil.

6. The filter device according to claim 1, wherein
an inductance value of the first coil is larger than an inductance value of the second coil, and
an inductance value of the fourth coil is larger than an inductance value of the third coil.

7. The filter device according to claim 1, wherein at least one of part of the first coil and part of the fourth coil is disposed outside the first region.

8. The filter device according to claim 1, wherein
each of the first coil and the fourth coil includes a plurality of plate electrodes disposed at dielectric layers different from one another, and a plurality of vias extending in the stacking direction,
the first coil includes a first plate electrode and a second plate electrode, and
one or some of the plate electrodes included in the fourth coil are disposed at a dielectric layer between the first plate electrode and the second plate electrode.

9. The filter device according to claim 1, wherein
each of the first coil and the fourth coil includes a plurality of plate electrodes disposed at dielectric layers different from one another, and a plurality of vias extending in the stacking direction, and
in at least one of the first coil and the fourth coil, an end portion of at least one or some of the plurality of plate electrodes included in the at least one of the first coil and the fourth coil are positioned outside an opening portion of the second coil in plan view in the second direction.

10. The filter device according to claim 1, wherein
the first filter circuit further includes
a first capacitor connected between the ground terminal and a connection node between the first coil and the second coil and
a second capacitor connected in parallel with the second coil.

11. The filter device according to claim 1, wherein
the second filter circuit further includes
a third capacitor connected to the input terminal,
a fourth capacitor connected between the third capacitor and the second output terminal, and
a fifth capacitor connected between the fourth coil and the ground terminal, and
the third coil is connected between the ground terminal and a connection node between the third capacitor and the fourth capacitor.

12. A radio frequency front-end circuit comprising:
the filter device according to claim 1.

13. The radio frequency front-end circuit according to Claim 12, further comprising:
a third filter circuit having a third frequency band different from the first frequency band and the second frequency band as a passband.

14. The filter device according to claim 1, wherein the first filter circuit is a low-pass filter and the second filter circuit is a high-pass filter.

15. The filter device according to claim 1, wherein the second direction is substantially perpendicular to the first direction.

16. The filter device according to claim 1, wherein the second coil is disposed at a first end portion of the multilayer body and the third coil is disposed at an opposing second end portion of the multilayer body.

17. A filter device, comprising:
a multilayer body including a plurality of dielectric layers stacked in a stacking direction, the multilayer body having a first principal surface and an opposing second principal surface;
an input terminal, a first terminal, and a second terminal disposed at the second principal surface;
first filter circuit coupled between the input terminal and the first terminal, the first filter circuit including a first planar coil having a winding axis parallel to the stacking direction; and
a second filter circuit coupled between the input terminal and the second terminal, the second filter circuit including a first vertical coil having a winding axis that intersects the stacking direction, wherein
a top end of the first vertical coil is located at a first height from the second principal surface, and
a top end of the first planar coil is located at a second height from the second principal surface, the second height being less than the first height.

18. The filter device according to claim 17, wherein, in plan view in the first direction, a winding direction of the first coil and a winding direction of the fourth coil are opposite to one another.
